(19) United States
(12) Patent Application Publication
(10) Pub. No.: US 2024/0006283 A1
(43) Pub. Date: Jan. 4, 2024

(54) EDGE DELAMINATION AND CRACK PREVENTION METHODS FOR SINX AND TI-CU ENABLED PACKAGES

(71) Applicant: Intel Corporation, Santa Clara, CA (US)

(72) Inventors: Suddhasattawa NAD, Chandler, AZ (US); Rahul N. MANEPALLI, Chandler, AZ (US); Gang DUAN, Chandler, AZ (US); Srinivas V. PIETAMBARAM, Chandler, AZ (US); Yi YANG, Gilbert, AZ (US); Marcel WALL, Phoenix, AZ (US); Darko GRUJICIC, Chandler, AZ (US); Haobo CHEN, Gilbert, AZ (US); Aaron GARELICK, Chandler, AZ (US)

(21) Appl. No.: 17/853,487

(22) Filed: Jun. 29, 2022

(51) Int. Cl. H01L 23/498; H01L 21/48

(52) U.S. Cl. CPC H01L 23/49822; H01L 23/49866; H01L 21/4857; H01L 2224/16225; H01L 24/16

(57) ABSTRACT

Embodiments disclosed herein include package substrates and methods of forming such substrates. In an embodiment, a package substrate comprises a core, a first layer over the core, where the first layer comprises a metal, and a second layer over the first layer, where the second layer comprises an electrical insulator. In an embodiment, the package substrate further comprises a third layer over the second layer, where the third layer comprises a dielectric material, and where an edge of the core extends past edges of the first layer, the second layer, and the third layer.

### TECHNICAL FIELD

Embodiments of the present disclosure relate to electronic packages, and more particularly to packaging architectures that include package substrates with edge architectures that mitigate cracks and delamination.

### BACKGROUND

As packaging substrates move progressively towards faster high speed input/output (HSIO) structures and higher routing densities, dry film applications are increasingly becoming technology enablers. One such application is the deposition of an adhesion layer over copper layers. The deposition may be implemented with a physical vapor deposition (PVD) process. The adhesion layer allows for the copper to be smooth (to improve routing speed) while still enabling good adhesion to overlying buildup film layers. For example, the adhesion layer may comprise SiNₓ. Additionally, seed layers may also be formed with PVD processes. For example, a titanium/copper seed layer may be used in some instances.

However, such architectures have a significant drawback. Particularly, the likelihood of interfacial package failure during unit singulation is increased. For SiNₓ layers, cutting through the SiNₓ film can result in interfacial delamination at the SiNₓ—buildup film interface. For Ti/Cu seed layers, residual film stress may result in the formation of cracks in the underlying core (e.g., glass core) substrate during singulation.

Accordingly, while such films enable improved HSIO structures, there are still manufacturing issues that need to be remedied.

### BRIEF DESCRIPTION OF THE DRAWINGS

FIG. 1 is a plan view illustration of a panel of package substrates with saw streets between the package substrates, in accordance with an embodiment.

FIG. 2A is a cross-sectional illustration of a panel after singulation, where the layers over the core are ablated with a laser and the core is sawed with a mechanical saw, in accordance with an embodiment.

FIG. 2B is a cross-sectional illustration of a panel after singulation, where the layers over the core are removed with an etching process, in accordance with an embodiment.

FIG. 2C is a cross-sectional illustration of a panel after singulation, where the metal layers are recessed prior to singulation, in accordance with an embodiment.

FIG. 3A is a cross-sectional illustration of a panel with layers over a core, in accordance with an embodiment.

FIG. 3B is a cross-sectional illustration of the panel after the layers over the core are ablated with a laser, in accordance with an embodiment.

FIG. 3C is a cross-sectional illustration of the panel after the core is singulated with a mechanical sawing process, in accordance with an embodiment.

FIG. 4A is a cross-sectional illustration of a panel with layers over a core, in accordance with an embodiment.

FIG. 4B is a cross-sectional illustration of the panel after portions of a buildup film layer and an adhesion layer are removed with a desmear process, in accordance with an embodiment.

FIG. 4C is a cross-sectional illustration of the panel after the metal layers are removed with an etching process, in accordance with an embodiment.

FIG. 4D is a cross-sectional illustration of the panel after the core is singulated with a mechanical sawing process, in accordance with an embodiment.

FIG. 5A is a cross-sectional illustration of a panel with a seed layer and a metal layer over the core, in accordance with an embodiment.

FIG. 5B is a cross-sectional illustration of the panel after the seed layer and metal layer are removed from the saw street with an etching process, in accordance with an embodiment.

FIG. 5C is a cross-sectional illustration of the panel after an adhesion layer and a buildup film layer are provided over the metal layer and the core, in accordance with an embodiment.

FIG. 5D is a cross-sectional illustration of the panel after the buildup film layer is removed from the saw street, in accordance with an embodiment.

FIG. 5E is a cross-sectional illustration of the panel after the adhesion layer and is removed from the saw street, in accordance with an embodiment.

FIG. 5F is a cross-sectional illustration of the panel after the core is singulated with a mechanical sawing process, in accordance with an embodiment.

FIG. 6A is a plan view illustration of a panel with a plurality of package substrates separated by saw streets, in accordance with an embodiment.

FIG. 6B is a plan view illustration of the panel after singulation.

FIG. 6C is a cross-sectional illustration of one of the package substrates from the panel, in accordance with an embodiment.

FIG. 7A is a plan view illustration of a panel with a plurality of package substrates separated by saw streets, in accordance with an embodiment.

FIG. 7B is a plan view illustration of one of the package substrates after singulation of the panel, in accordance with an embodiment.

FIG. 7C is a cross-sectional illustration of the package substrate in FIG. 7B, in accordance with an embodiment.

FIG. 8 is a cross-sectional illustration of an electronic system with a package substrate that has edges that are offset from each other, in accordance with an embodiment.

FIG. 9 is a schematic of a computing device built in accordance with an embodiment.

### EMBODIMENTS OF THE PRESENT DISCLOSURE

Described herein are packaging architectures that include package substrates with edge architectures that mitigate cracks and delamination, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, layers that have been added to the package substrate to improve high speed input/output (HSIO) architectures may result in the formation of defects during singulation of the panel. For example, cutting through the adhesion layer (e.g., SiNₓ) may result in interfacial delamination at the adhesion layer—buildup film layer interface. Additionally, the seed layer can generate residual film stress that causes a crack in the underlying core (e.g., a glass core) during singulation.

Accordingly, embodiments disclosed herein include singulation processes that reduce or eliminate the risk of delamination and core cracking. Particularly, the layers over the core are singulated first with one or more different processes. For example, the layers may be singulated with a laser ablation process, an etching process, a desmear process, or the like. After the core is exposed, the core may then be singulated with a mechanical sawing process.

Methods, such as those described herein, also result in novel edge topographies. That is, one or more of the edges of the singulated package substrates may have an edge architecture that can be used to indicate that one or more of the methods have been used to form the package substrate. In one instance, a laser burned region is provided over the core, and an edge of the burned region is inset from the edge of the core. In another embodiment, the adhesion layer includes a sloped edge. The sloped edge may connect an edge of the buildup film layer to an edge of the metal layer. Additionally, edges of the metal layer, the adhesion layer, and the buildup film layer may be set back from an edge of the core.

In embodiments described herein, the core of the package substrate may be an organic core (e.g., with fiber reinforcement). In other embodiments, the core of the package substrate may be a glass core. Other core architectures may also be included in accordance with different embodiments. Additionally, the package substrates may be coreless in some instances. Embodiments disclosed herein may be used in various package substrate architectures, such as, but not limited to, wafer/panel fan out, glass core, coreless, molded packages, reconstituted mold layers, and the like.

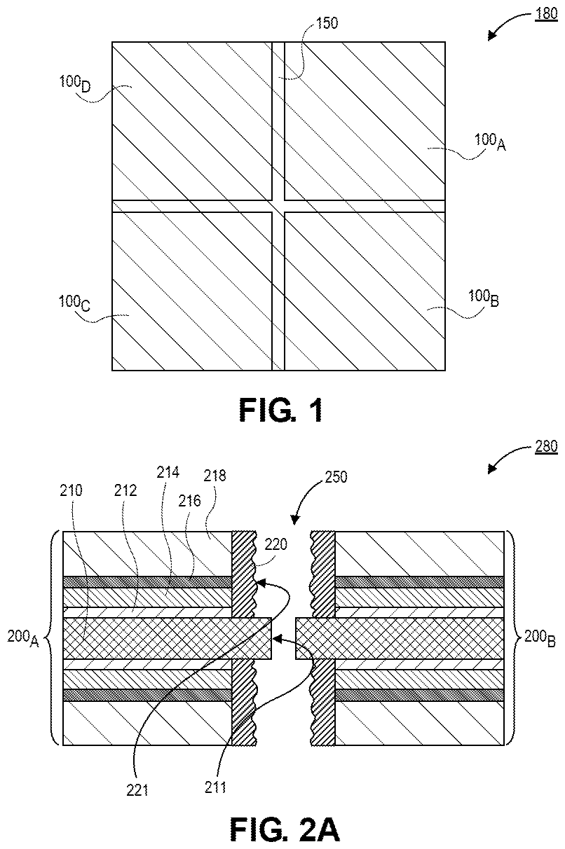

Referring now to FIG. 1 a plan view illustration of a panel 180 is shown, in accordance with an embodiment. In an embodiment, the panel 180 may include a plurality of package substrates 100 that are fabricated with each other substantially in parallel. For example four package substrates 100A-100D are shown in FIG. 1. The package substrates 100 may be separated from each other by a saw street 150. In an embodiment, the panel 180 may be a full panel, a quarter panel, or any other form factor. The individual package substrates 100 may be fabricated with any process used to form package substrates. For example, the package substrates 100 may have a core with one or more routing layers provided over the core. In a particular embodiment, the routing layers may be metal (e.g., copper) layers that are formed over seed layers, such as a seed layer comprising titanium. Additionally, the metal layers may be covered by an adhesion layer. For example, the adhesion layer may include silicon and nitrogen (e.g., SiNₓ).

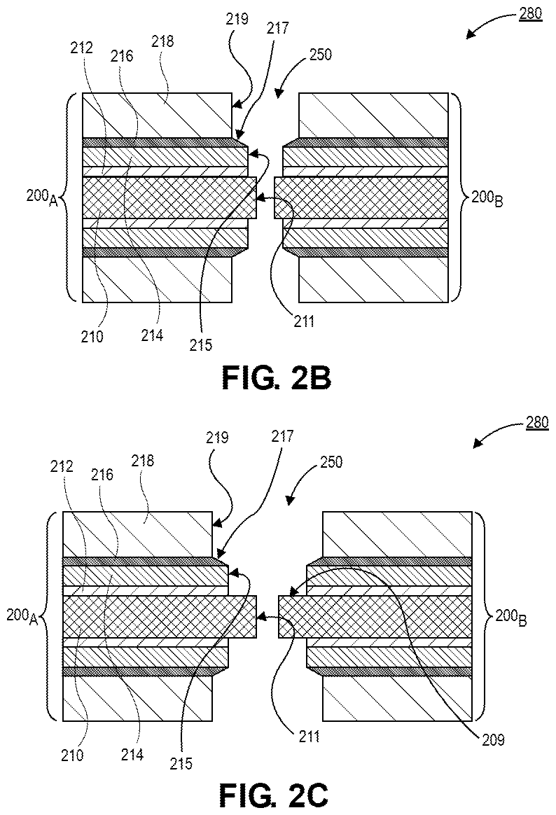

Referring now to FIG. 2A, a cross-sectional illustration of a portion of a panel 280 is shown, in accordance with an embodiment. In the illustrated embodiment, the panel 280 has been singulated into a pair of package substrates 200A and 200B. Each of the package substrates 200 may include a core 210. For example, the core 210 may be an organic core material, a glass core material, or any other suitable core material. A seed layer 212 may be provided on the core 210. For example, the seed layer 212 may comprise titanium in some embodiments. Though, it is to be appreciated that other metals or alloys with different metal combinations may also be used as the seed layer 212. The seed layer 212 may be formed with any suitable process. For example, the seed layer 212 may be formed with a physical vapor deposition (PVD) process.

In an embodiment, a metal layer 214 is provided over the seed layer 212. The metal layer 214 may be formed with a plating process, using the seed layer 212 to initiate growth of the metal layer 214. The metal layer 214 may be any electrically conductive material. For example, the metal layer 214 may comprise copper. In an embodiment, an adhesion layer 216 is provided over the metal layer 214. As used herein, an adhesion layer 216 may refer to a layer that improves the adhesion between two other layers. For example, the adhesion between the buildup layer 218 and the metal layer 214 is improved by the adhesion layer 216. In a particular embodiment, the adhesion layer 216 comprises silicon and nitrogen (e.g., SiNₓ). The adhesion layer 216 may be an electrically insulating layer. In an embodiment, the buildup layer 218 may be any typical organic buildup film used in semiconductor packaging applications.

In an embodiment, the layers 212, 214, 216, and 218 may also be provided on the backside of the core 210. In the illustrated embodiment, a single routing layer (i.e., metal layer) is shown for simplicity. However, it is to be appreciated that package substrates 200 may include any number of routing layers (and corresponding seed layers 212, adhesion layers 216, and buildup layers 218).

In an embodiment, the saw street 250 may be singulated in order to separate the first package substrate 200A from the second package substrate 200B. In a particular embodiment, the layers 212, 214, 216, and 218 over the core 210 may be singulated with a laser ablation process. The use of a laser ablation process may result in the formation of burned regions 220 at the edges of the package substrates 200. The burned regions 220 may comprise various atoms from the different layers 212, 214, 216, and 218. For example, the burned regions 220 may comprise one or more of carbon, nitrogen, silicon, copper, and titanium. The burned regions 220 may be distinguishable from the layers 212, 214, 216, and 218. That is, in a cross-sectional illustration of the edge of the package substrate 200, the layers 212, 214, 216, and 218 may terminate, and the burned region 220 may continue to the edge of the package substrate 200. Additionally, the outer edge 221 of the burned region 220 may be set back from the edge 211 of the core 210. That is, the edge 211 may extend past the edge 221 in some embodiments. This is because the laser ablation process may have a wider kerf than a mechanical drilling process used to singulate the core 210.

Referring now to FIG. 2B, a cross-sectional illustration of a portion of a panel 280 is shown, in accordance with an additional embodiment. In an embodiment, the panel 280 may comprise a first package substrate 200A that is singulated from a second package substrate 200B. The layers 210, 212, 214, 216, and 218 of the package substrates 200 may be substantially similar to the layers described above with respect to FIG. 2A. That is, the package substrates 200 may include a core 210, a seed layer 212, a metal layer 214, an adhesion layer 216, and a buildup layer 218. However, the process used to singulate the package substrates 200 is different, and leads to a difference in the edge profile of the package substrates 200.

As shown, the core 210 may have a first edge 211. The first edge 211 may be formed with a mechanical sawing process. The seed layer 212 and the metal layer 214 may have an edge 215 that is set back from the first edge 211. For example, the seed layer 212 and the metal layer 214 may be singulated with a wet etching process. The adhesion layer 216 may have an edge 217 that is sloped. The slope of the edge 217 may connect the edge 215 of the metal layer 214 to an edge 219 of the buildup layer 218. The edges 217 and 219 may also be set back from the first edge 211 of the core 210.

Referring now to FIG. 2C, a cross-sectional illustration of a portion of a panel 280 is shown, in accordance with an additional embodiment. In an embodiment, the panel 280 may comprise a first package substrate 200A that is singulated from a second package substrate 200B. The layers 210, 212, 214, 216, and 218 of the package substrates 200 may be substantially similar to the layers described above with respect to FIG. 2B. That is, the package substrates 200 may include a core 210, a seed layer 212, a metal layer 214, an adhesion layer 216, and a buildup layer 218. However, the process used to singulate the package substrates 200 is different, and leads to a difference in the edge profile of the package substrates 200.

Particularly, FIG. 2C differs from FIG. 2B in the amount of the top surface 209 of the core 210 that is exposed. Due to the processing operations (described in greater detail below) the sidewalls 215 of the seed layer 212 and the metal layer 214 are set back further from the edge 211 than what is shown in FIG. 2B. Similar to the embodiment in FIG. 2B, the sidewall 217 of the adhesion layer 216 is sloped in order to connect the sidewall 219 of the buildup layer 218 to the sidewall 215 of the metal layer 214.

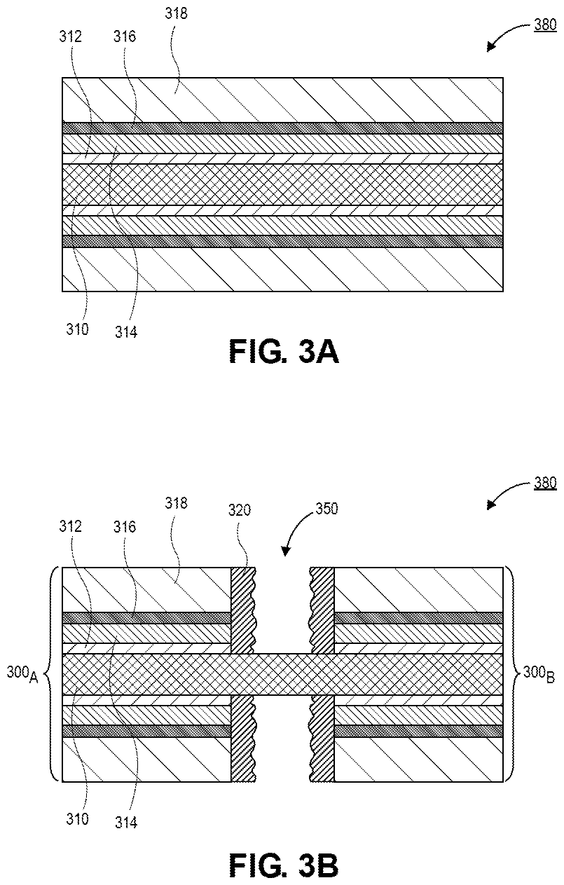

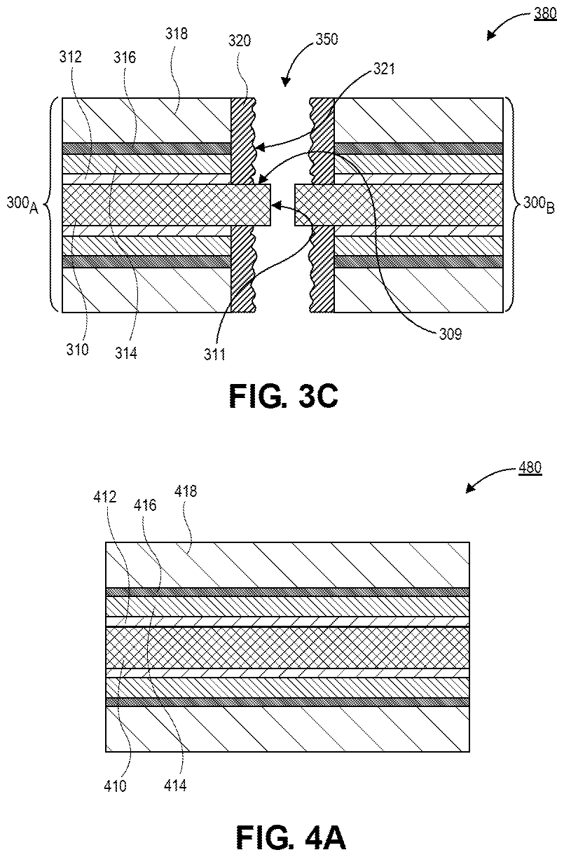

Referring now to FIGS. 3A-3C, a series of cross-sectional illustrations depicting a process to form singulated packages 300 from a panel 380 is shown, in accordance with an embodiment. In an embodiment, the process shown in FIGS. 3A-3C may result in the formation of package substrates substantially similar to the package substrates 200 shown in FIG. 2A.

Referring now to FIG. 3A, a cross-sectional illustration of a panel 380 is shown, in accordance with an embodiment. In an embodiment, the panel 380 may comprise a core 310. The core 310 may be any suitable core material, such as those described in greater detail above. In a particular embodiment, the core 310 may comprise glass. In an embodiment, layers 312, 314, 316, and 318 may be provided above and below the core 310. Layer 312 may be a seed layer, layer 314 may be a metal layer, layer 316 may be an adhesion layer, and layer 318 may be a buildup layer. Layers 312, 314, 316, and 318 may be substantially similar to similarly named layers described in greater detail above.

Referring now to FIG. 3B, a cross-sectional illustration of the panel 380 after a laser ablation process is shown, in accordance with an embodiment. In an embodiment, the laser ablation process may be used to open up the saw street 350 between a first package substrate 300A and a second package substrate 300B. The laser ablation process may singulate the layers 312, 314, 316, and 318 above and below the core 310. That is, the laser ablation process may not cut into or through the core 310. In an embodiment, the laser ablation process may result in the formation of burned regions 320 at the edge of layers 312, 314, 316, and 318. The burned region 320 may comprise elements or atoms of one or more of the layers 312, 314, 316, and 318. However, it is to be appreciated that there will be a distinct difference between the burned region 320 and the layers 312, 314, 316, and 318 shown in cross-sectional views of the package substrates 300.

Referring now to FIG. 3C, a cross-sectional illustration of the panel 380 after the core 310 is singulated is shown, in accordance with an embodiment. In an embodiment, the core 310 may be singulated with a mechanical sawing process. The singulation of the core 310 may have a kerf that is narrower than the kerf of the laser ablation process. That is, a sidewall 311 of the core 310 may extend further out than a sidewall 321 of the burned region 320. Stated in another way, the sidewall 321 of the burned region 320 may be set back from the sidewall 311 of the core 310. Since the sidewall 321 is set back from the sidewall 311, a portion of the top surface 309 of the core 310 may be exposed in some embodiments.

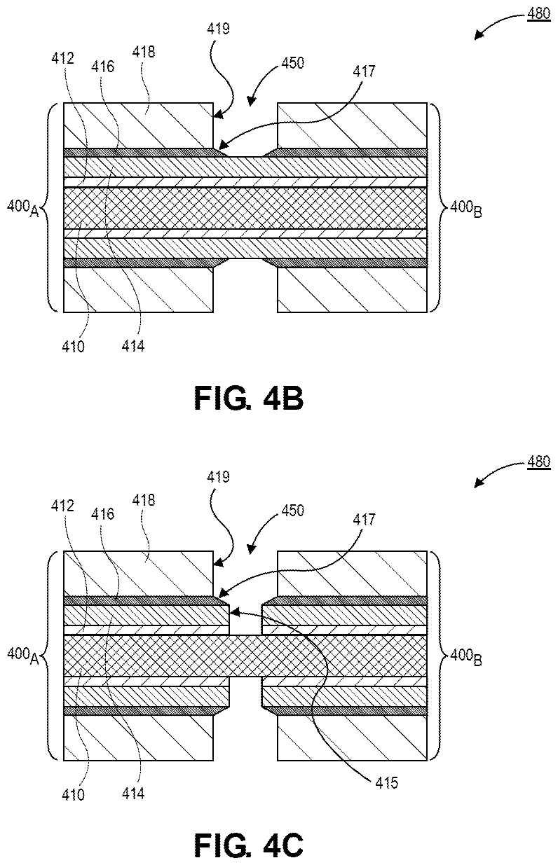

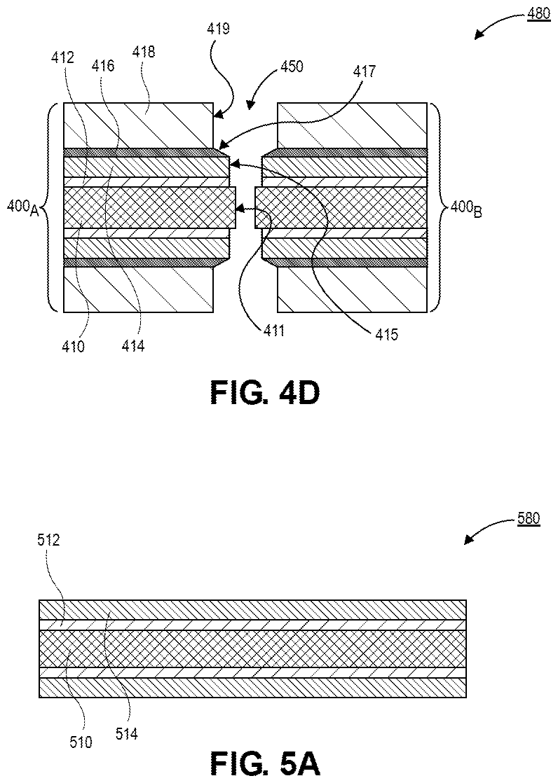

Referring now to FIG. 4A, a cross-sectional illustration of a panel 480 is shown, in accordance with an embodiment. In an embodiment, the panel 480 may comprise a core 410. The core 410 may be any suitable core material, such as those described in greater detail above. In a particular embodiment, the core 410 may comprise glass. In an embodiment, layers 412, 414, 416, and 418 may be provided above and below the core 410. Layer 412 may be a seed layer, layer 414 may be a metal layer, layer 416 may be an adhesion layer, and layer 418 may be a buildup layer. Layers 412, 414, 416, and 418 may be substantially similar to similarly named layers described in greater detail above.

Referring now to FIG. 4B, a cross-sectional illustration of the panel 480 after the buildup layer 418 and the adhesion layer 416 are removed in the saw street 450 is shown, in accordance with an embodiment. Removal of portions of buildup layer 418 and adhesion layer 416 may begin the process of singulating the pair of package substrates 400A and 400B. In an embodiment, the buildup layer 418 may be removed with an etching process. For example, a dry etching process may be used in some embodiments. In an embodiment, the adhesion layer 416 may also be removed with a dry process. For example, a dry desmear process may be used to remove the adhesion layer 416. The dry desmear process may result in a sloped sidewall surface 417. The top of the sidewall 417 may be adjacent to the sidewall 419 of the buildup layer 418.

Referring now to FIG. 4C, a cross-sectional illustration of the panel 480 after the metal layer 414 and the seed layer 412 are etched is shown, in accordance with an embodiment. In an embodiment, the metal layer 414 and the seed layer 412 may be etched with a wet etching process. The metal layer 414 and the seed layer 412 may have substantially vertical sidewalls in some embodiments. As shown, the sloped sidewall 417 may have a bottom that is adjacent to the sidewall 415 of the metal layer 414. That is, the sloped sidewall 417 may be considered to be joining the sidewall 419 of the buildup layer 418 to the sidewall 415 of the metal layer 414.

Referring now to FIG. 4D, a cross-sectional illustration of the panel 480 after the core 410 is singulated is shown, in accordance with an embodiment. In an embodiment, the core 410 may be singulated with a mechanical sawing process. The sidewall 411 of the core 410 may extend out past the sidewalls of the layers 412, 414, 416, and 418. That is, sidewalls 419, 417, and 415 may be set back from the sidewall 411 in some embodiments. This is because the kerf of the mechanical sawing process may be narrower than the width of the saw street 450 in the layers above and below the core 410.

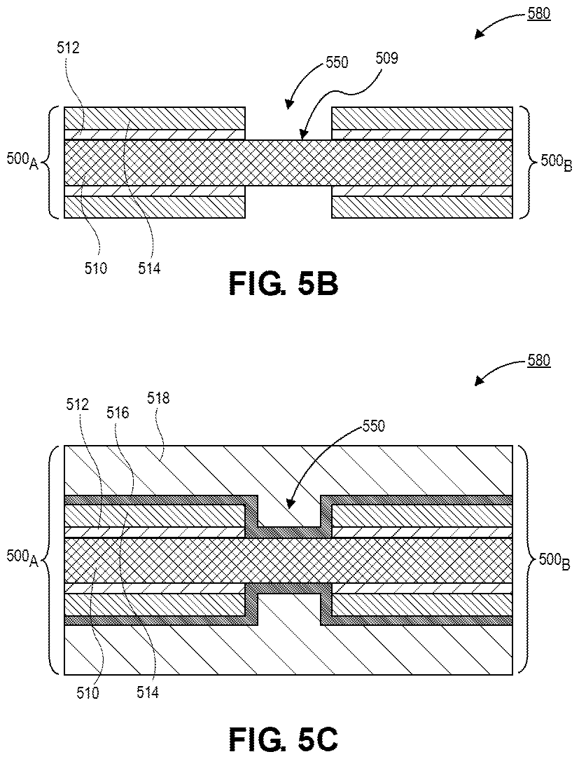

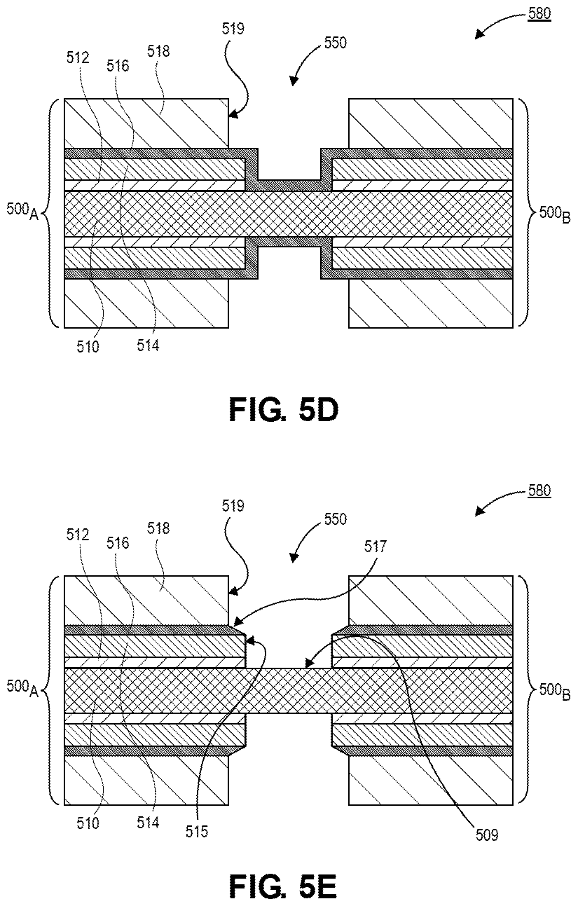

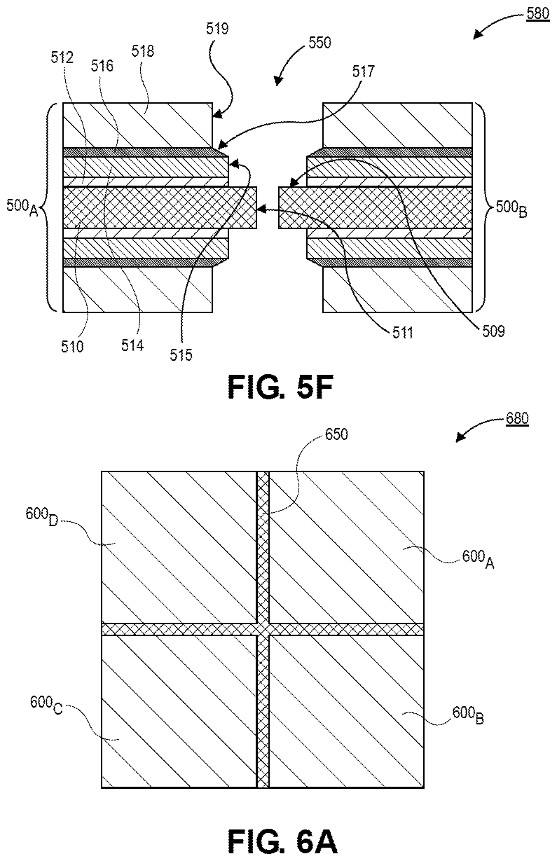

Referring now to FIG. 5A, a cross-sectional illustration of a panel 580 is shown, in accordance with an embodiment. In an embodiment, the panel 580 may comprise a core 510. The core 510 may be substantially similar to any of the core layers described in greater detail above. In an embodiment, seed layers 512 and metal layers 514 may be provided over and under the core 510. The seed layer 512 and the metal layer 514 may be substantially similar to any of the seed layers or metal layers described in greater detail above.

Referring now to FIG. 5B, a cross-sectional illustration of the panel 580 after a saw street 550 is defined between a first package substrate 500A and a second package substrate 500E is shown, in accordance with an embodiment. In an embodiment, the saw street 550 may be defined with a patterning and etching process used to define the widths of the seed layer 512 and the metal layer 514. As such, a top surface 509 of the core 510 is exposed in the saw street 550.

Referring now to FIG. 5C, a cross-sectional illustration of the panel 580 after an adhesion layer 516 and a buildup layer 518 are formed is shown, in accordance with an embodiment. In an embodiment, the adhesion layer 516 is a conformal layer and is disposed over the metal layer 514 and also over the exposed portions of the core 510. The buildup layer 518 may be provided over the adhesion layer 516. In an embodiment, the adhesion layer 516 and the buildup layer 518 may be substantially similar to adhesion layers and buildup layers described in greater detail above.

Referring now to FIG. 5D, a cross-sectional illustration of the panel 580 after the buildup layer 518 in the saw street 550 is removed is shown, in accordance with an embodiment. In an embodiment, the buildup layer 518 may be removed with an etching process or the like. For example, a dry etching process may be used in some embodiments. As such, a sidewall 519 of the buildup layer 518 may be substantially vertical.

Referring now to FIG. 5E, a cross-sectional illustration of the panel 580 after the adhesion layer 516 is removed from the saw street 550 is shown, in accordance with an embodiment. The adhesion layer 516 may be removed with a dry desmear process in some embodiments. The removal process may result in the sidewall 517 of the adhesion layer 516 being sloped. As shown, the sloped sidewall 517 may connect the sidewall 519 of the buildup layer 518 to the sidewall 515 of the metal layer 514. Additionally, removal of the adhesion layer 516 may expose a portion of the top surface 509 of the core 510.

Referring now to FIG. 5F, a cross-sectional illustration of the panel 580 after the core 510 is singulated is shown, in accordance with an embodiment. In an embodiment, the core 510 may be singulated with a mechanical sawing process. The sidewall 511 of the core 510 may extend out past the sidewalls of the layers 512, 514, 516, and 518. That is, sidewalls 519, 517, and 515 may be set back from the sidewall 511 in some embodiments. This is because the kerf of the mechanical sawing process may be narrower than the width of the saw street 550 in the layers above and below the core 510.

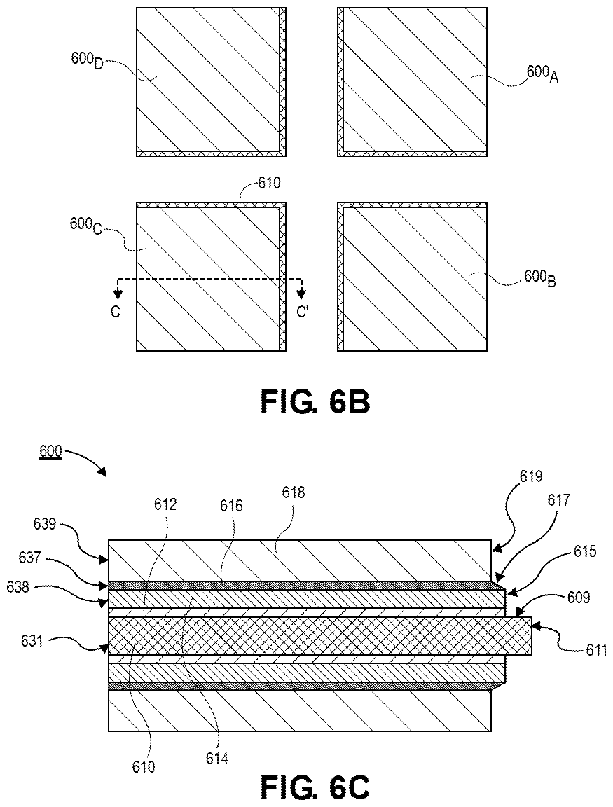

Referring now to FIG. 6A, a plan view illustration of a panel 680 is shown, in accordance with an embodiment. As shown, the panel 680 may include a plurality of package substrates 600A-600D. Portions of the core may be exposed in the saw streets 650. Particularly, it is noted that the saw streets 650 are only provided along a pair of edges for each of the package substrates 600A-600D. That is, the outside edges of each of the package substrates 600A-600D are coved by the buildup layers of the package substrates 600.

Referring now to FIG. 6B, a plan view illustration of the panel 680 after singulation is shown, in accordance with an embodiment. As shown, a portion of the core 610 may be exposed along a pair of edges of each of the package substrates 600. The core 610 may be along adjacent edges of each of the package substrates 600.

Referring now to FIG. 6C, a cross-sectional illustration of one of the package substrates 600 is shown, in accordance with an embodiment. For example, the cross-section may be along line C-C′ in FIG. 6B. As shown, the package substrate 600 comprises a core 610. A seed layer 612 may be over the core 610, and a metal layer 614 may be over the seed layer 612. An adhesion layer 616 is provided over the metal layer 614, and a buildup layer 618 is provided over the adhesion layer 616.

In an embodiment, a first edge (i.e., the right edge in FIG. 6C) includes a stepped profile. That is, edge 611 of the core 610 may extend out past edges of the other layers. For example, edge 615 of the metal layer 614 may be set back from the edge 611. In an embodiment, edge 619 of the buildup layer 618 may be set back from the edge 615. In some embodiments, the edge 617 of the adhesion layer 616 may be sloped. The sloped edge 617 may connect the edge 619 to the edge 615.

In an embodiment, the second edge (i.e., the left edge in FIG. 6C) may be a vertical edge. That is edge 631 of the core 610, edge 638 of the metal layer 614, edge 637 of the adhesion layer 616, and edge 639 of the buildup layer 618 may be substantially coplanar with each other. This is because the second edge is not singulated.

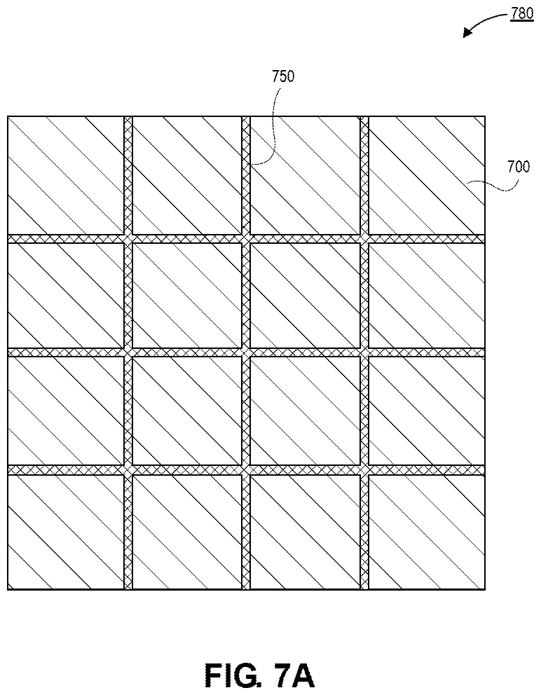

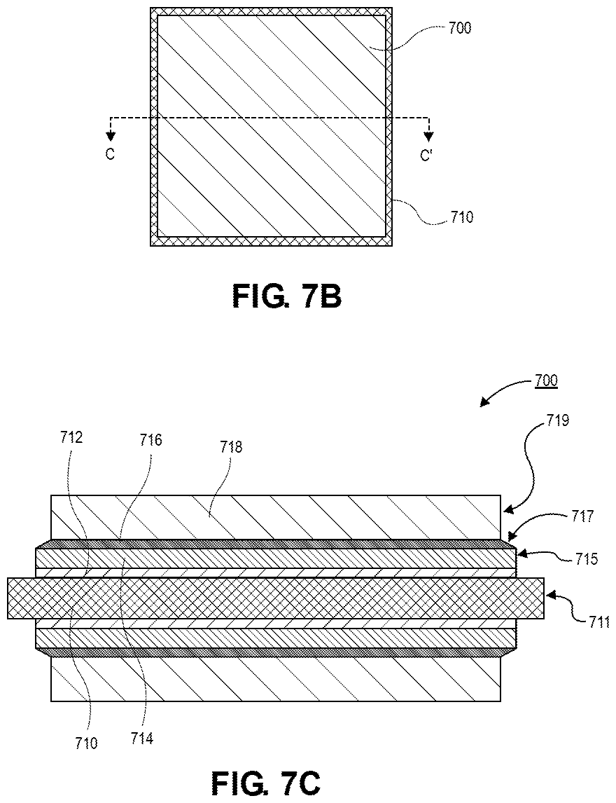

Referring now to FIG. 7A, a plan view illustration of a panel 780 is shown, in accordance with an additional embodiment. As shown, a plurality of package substrates 700 are provided. The package substrates 700 may be separated from each other by a saw street 750. In the illustrated embodiment, sixteen package substrates 700 are shown in a four-by-four arrangement. Accordingly, some of the package substrates 700 may have saw streets 750 along all four sides of the package substrate 700, some of the package substrates 700 may have saw streets 750 along three sides of the package substrate 700, and some of the package substrates 700 may have saw streets 750 along two sides of the package substrate 700.

Referring now to FIG. 7B, a plan view illustration of one of the package substrates 700 after singulation is shown, in accordance with an embodiment. As shown, the package substrate 700 includes exposed portions of the core 710 around an entire perimeter of the package substrate 700.

Referring now to FIG. 7C, a cross-sectional illustration of the package substrate 700 in FIG. 7B along line C-C′ is shown, in accordance with an embodiment. In an embodiment, both edges (i.e., the left edge and the right edge) of the package substrate 700 may be stepped profiles. For example, a first edge 711 of the core 710 may extend out past the other layers. An edge 715 of the metal layer 714 and the seed layer 712 may be set back from the edge 711. An edge 719 of the buildup layer 718 may be set back from the edge 715. Additionally, the edge 717 of the adhesion layer 716 may be sloped in order to connect the edge 719 to the edge 715.

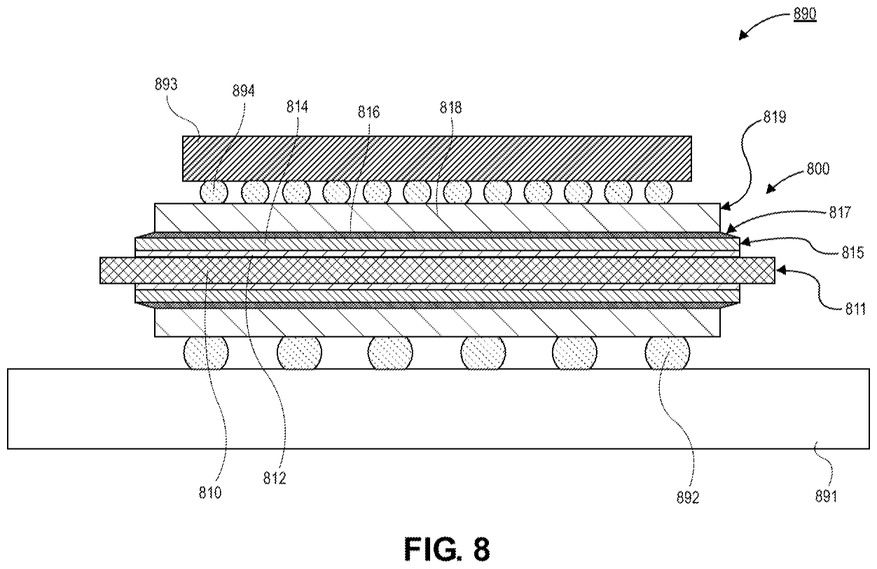

Referring now to FIG. 8, a cross-sectional illustration of an electronic system 890 is shown, in accordance with an embodiment. In an embodiment, the electronic system 890 may comprise a board 891, such as a printed circuit board (PCB). In an embodiment, a package substrate 800 may be coupled to the board 891 by interconnects 892, such as solder balls or the like. In an embodiment, a die 893 may be coupled to the package substrate 800 by interconnects 894. The interconnects 894 may be any first level interconnect (FLI) architecture.

In an embodiment, the package substrate 800 may include a core 810. A seed layer 812 may be provided over the core 810. A metal layer 814 may be provided over the seed layer 812. An adhesion layer 816 may be provided over the metal layer 814. In an embodiment, a buildup layer 818 is provided over the adhesion layer 816. In the illustrated embodiment, a single metal layer 814 is shown. However, it is to be appreciated that additional metal layers (with corresponding seed layers, adhesion layers, and buildup layers) may be provided on the package substrate 800.

In an embodiment, the edges of the package substrate 800 may have a stepped profile. For example, a first edge 811 of the core 810 may extend out past the other layers. An edge 815 of the metal layer 814 and the seed layer 812 may be set back from the edge 811. An edge 819 of the buildup layer 818 may be set back from the edge 815. Additionally, the edge 817 of the adhesion layer 816 may be sloped in order to connect the edge 819 to the edge 815.

In FIG. 8, a particular package substrate 800 architecture is shown. However, it is to be appreciated that the electronic system 890 may include any package substrate architecture described herein.

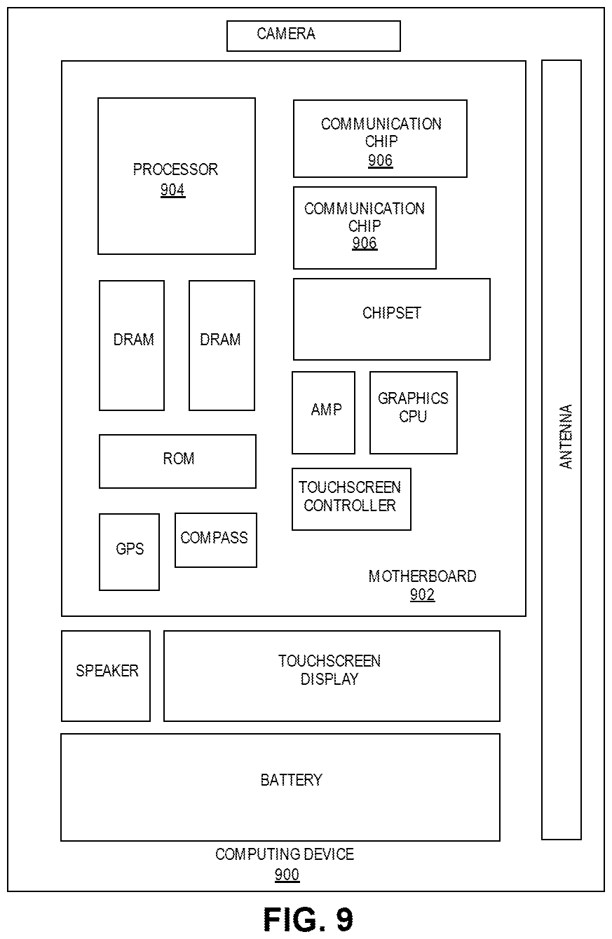

FIG. 9 illustrates a computing device 900 in accordance with one implementation of the invention. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the invention, the integrated circuit die of the processor may be part of an electronic system that comprises a package substrate with a stepped edge profile that includes a core that extends out past the edges of the overlying layers, in accordance with embodiments described herein. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the invention, the integrated circuit die of the communication chip may be part of an electronic system that comprises a package substrate with a stepped edge profile that includes a core that extends out past the edges of the overlying layers, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a package substrate, comprising: a core; a first layer over the core, wherein the first layer comprises a metal; a second layer over the first layer, wherein the second layer comprises an electrical insulator; and a third layer over the second layer, wherein the third layer comprises a dielectric material, and wherein an edge of the core extends past edges of the first layer, the second layer, and the third layer.

Example 2: the package substrate of Example 1, wherein a burned region is provided at the edges of the first layer, the second layer and the third layer.

Example 3: the package substrate of Example 2, wherein the burned region is a composite material that includes atoms of one or more of the first layer, the second layer, and the third layer.

Example 4: the package substrate of Example 2 or Example 3, wherein the edge of the core extends past an edge of the burned region.

Example 5: the package substrate of Examples 1-4, wherein the first layer comprises a seed layer and metal layer over the seed layer.

Example 6: the package substrate of Example 5, wherein the seed layer comprises titanium, and wherein the metal layer comprises copper.

Example 7: the package substrate of Examples 1-6, wherein the second layer comprises silicon and nitrogen.

Example 8: the package substrate of Examples 1-7, wherein the third layer comprises a buildup material.

Example 9: the package substrate of Examples 1-8, wherein a second edge of the core opposite from the edge of the core is substantially coplanar with second edges of the first layer, the second layer, and the third layer.

Example 10: the package substrate of Examples 1-9, further comprising: a fourth layer under the core, wherein the fourth layer comprises a metal; a fifth layer under the fourth layer, wherein the fifth layer comprises an electrical insulator; and a sixth layer under the fifth layer, wherein the sixth layer comprises a dielectric material, and wherein the edge of the core extends past edges of the fourth layer, the fifth layer, and the sixth layer.

Example 11: a package substrate, comprising: a core; a first layer over the core, wherein the first layer comprises a metal; a second layer over the first layer, wherein the second layer comprises an electrical insulator, and wherein an edge of the second layer is sloped; and a third layer over the second layer, wherein the third layer comprises a dielectric material.

Example 12: the package substrate of Example 11, wherein the first layer has a first edge, wherein the third layer has a second edge, and wherein the second edge is set back from the first edge.

Example 13: the package substrate of Example 12, wherein a top of the edge of the second layer is in contact with the second edge and a bottom of the edge of the second layer is in contact with the first edge.

Example 14: the package substrate of Example 12 or Example 13, wherein the first edge, the second edge, and the edge of the second layer are set back from a third edge of the core.

Example 15; the package substrate of Examples 11-14, wherein the first layer comprises a seed layer and metal layer.

Example 16: the package substrate of Example 15, wherein the seed layer comprises titanium, and wherein the metal layer comprises copper.

Example 17: the package substrate of Examples 11-16, wherein the second layer comprises silicon and nitrogen.

Example 18: the package substrate of Examples 11-17, wherein the third layer comprises a buildup material.

Example 19: the package substrate of Examples 11-18, wherein a top surface of the core is exposed.

Example 20: a method of forming a package substrate, comprising: forming a first layer, a second layer, and a third layer over a core; forming an opening through the third layer and the second layer, wherein an edge of the second layer is sloped; forming an opening through the first layer to expose the core; and sawing through the core.

Example 21: the method of Example 20, wherein the opening through the second layer is formed with a dry desmear process.

Example 22: the method of Example 20 or Example 21, wherein the opening through the first layer is formed with a wet etching process.

Example 23: the method of Examples 20-22, wherein sawing through the core is done with a mechanical saw.

Example 24: an electronic system, comprising: a board; a package substrate coupled to the board, wherein the package substrate comprises: a core; and a routing layer over the core, wherein an edge of the routing layer is set back from an edge of the core; and a die coupled to the package substrate.

Example 25: the electronic system of Example 24, wherein the package substrate further comprises a second layer over the routing layer, wherein the second layer comprises silicon and nitrogen, and wherein an edge of the second layer is sloped.

What is claimed is:

1. A package substrate, comprising:
a core;
a first layer over the core, wherein the first layer comprises a metal;
a second layer over the first layer, wherein the second layer comprises an electrical insulator; and
a third layer over the second layer, wherein the third layer comprises a dielectric material, and wherein an edge of the core extends past edges of the first layer, the second layer, and the third layer.

2. The package substrate of claim 1, wherein a burned region is provided at the edges of the first layer, the second layer and the third layer.

3. The package substrate of claim 2, wherein the burned region is a composite material that includes atoms of one or more of the first layer, the second layer, and the third layer.

4. The package substrate of claim 2, wherein the edge of the core extends past an edge of the burned region.

5. The package substrate of claim 1, wherein the first layer comprises a seed layer and metal layer over the seed layer.

6. The package substrate of claim 5, wherein the seed layer comprises titanium, and wherein the metal layer comprises copper.

7. The package substrate of claim 1, wherein the second layer comprises silicon and nitrogen.

8. The package substrate of claim 1, wherein the third layer comprises a buildup material.

9. The package substrate of claim 1, wherein a second edge of the core opposite from the edge of the core is substantially coplanar with second edges of the first layer, the second layer, and the third layer.

10. The package substrate of claim 1, further comprising:
a fourth layer under the core, wherein the fourth layer comprises a metal;
a fifth layer under the fourth layer, wherein the fifth layer comprises an electrical insulator; and
a sixth layer under the fifth layer, wherein the sixth layer comprises a dielectric material, and wherein the edge of the core extends past edges of the fourth layer, the fifth layer, and the sixth layer.

11. A package substrate, comprising:
a core;
a first layer over the core, wherein the first layer comprises a metal;
a second layer over the first layer, wherein the second layer comprises an electrical insulator, and wherein an edge of the second layer is sloped; and
a third layer over the second layer, wherein the third layer comprises a dielectric material.

12. The package substrate of claim 11, wherein the first layer has a first edge, wherein the third layer has a second edge, and wherein the second edge is set back from the first edge.

13. The package substrate of claim 12, wherein a top of the edge of the second layer is in contact with the second edge and a bottom of the edge of the second layer is in contact with the first edge.

14. The package substrate of claim 12, wherein the first edge, the second edge, and the edge of the second layer are set back from a third edge of the core.

15. The package substrate of claim 11, wherein the first layer comprises a seed layer and metal layer.

16. The package substrate of claim 15, wherein the seed layer comprises titanium, and wherein the metal layer comprises copper.

17. The package substrate of claim 11, wherein the second layer comprises silicon and nitrogen.

18. The package substrate of claim 11, wherein the third layer comprises a buildup material.

19. The package substrate of claim 11, wherein a top surface of the core is exposed.

20. A method of forming a package substrate, comprising:
forming a first layer, a second layer, and a third layer over a core;
forming an opening through the third layer and the second layer, wherein an edge of the second layer is sloped;
forming an opening through the first layer to expose the core; and
sawing through the core.

21. The method of claim 20, wherein the opening through the second layer is formed with a dry desmear process.

22. The method of claim 20, wherein the opening through the first layer is formed with a wet etching process.

23. The method of claim 20, wherein sawing through the core is done with a mechanical saw.

24. An electronic system, comprising:
a board;
a package substrate coupled to the board, wherein the package substrate comprises:
a core; and
a routing layer over the core, wherein an edge of the routing layer is set back from an edge of the core; and
a die coupled to the package substrate.

25. The electronic system of claim 24, wherein the package substrate further comprises a second layer over the routing layer, wherein the second layer comprises silicon and nitrogen, and wherein an edge of the second layer is sloped.
